(19) United States
(12) Patent Application Publication
(10) Pub. No.: US 2024/0306478 A1
(43) Pub. Date: Sep. 12, 2024

(54) DISPLAY DEVICE AND METHOD OF MANUFACTURING THE SAME

(71) Applicant: Samsung Display Co., LTD., Yongin-si (KR)

(72) Inventors: SANGDUK LEE, Yongin-si (KR); HOIKWAN LEE, Yongin-si (KR); EUN-KYUNG YEON, Yongin-si (KR); HYUNKYUNG YUN, Yongin-si (KR)

(21) Appl. No.: 18/394,620

(22) Filed: Dec. 22, 2023

(30) Foreign Application Priority Data
Mar. 8, 2023 (KR) 10-2023-0030688

(51) Int. Cl. H10K 59/80; H10K 71/00

(52) U.S. Cl. CPC H10K 59/8792; H10K 71/00

(57) ABSTRACT

A display device includes a display panel including a display area and a non-display area defined adjacent to the display area, an optical layer disposed on the display panel, a light-blocking layer disposed on the optical layer and including at least one side surface protruding further than a side surface of the optical layer in a cross-section, and a coating window disposed on the light-blocking layer and including a resin material.

This application claims priority to Korean Patent Application No. 10-2023-0030688, filed on Mar. 8, 2023, and all the benefits accruing therefrom under 35 U.S.C. § 119, the content of which in its entirety is herein incorporated by reference.

### BACKGROUND

### 1. Field

The disclosure relates to a display device and a method of manufacturing the same. More particularly, the disclosure relates to a display device including a coating window and a method of manufacturing the display device.

### 2. Description of the Related Art

Display devices, such as a television set, a monitor, a smart phone, and a tablet computer, that provide images to a user include a display panel to display the images. Various types of display panels, such as a liquid crystal display panel, an organic light-emitting display panel, an organic light-emitting display panel, an electrowetting display panel, and an electrophoretic display panel, are being developed. In addition, the display device includes a window that protects the display panel. The window is attached to the display panel through a lamination process.

### SUMMARY

The disclosure provides a display device including a coating window.

The disclosure provides a method of manufacturing the display device including the coating window.

An embodiment of the inventive concept provides a display device including a display panel including a display area and a non-display area defined adjacent to the display area, an optical layer disposed on the display panel, a light-blocking layer disposed on the optical layer and including at least one side surface protruding further than a side surface of the optical layer when viewed in a cross-section, and a coating window disposed on the light-blocking layer and including a resin material.

In an embodiment, the coating window may include a side surface aligned with the at least one side surface of the light-blocking layer.

In an embodiment, the coating window may cover the light-blocking layer and the optical layer.

In an embodiment, the display device may further include a driving chip disposed on the display panel and spaced apart from the optical layer in a plan view, and the light-blocking layer may overlaps an area between the optical layer and the driving chip in the plan view.

In an embodiment, the light-blocking layer may be a rigid substrate disposed to overlap the non-display area and including a light-blocking material.

In an embodiment, the light-blocking layer may include a first light-blocking area, a second light-blocking area, a third light-blocking area, and a fourth light-blocking area, and the first light-blocking area includes the at least one side surface, and the first light-blocking area may have a width equal to or greater than about 2 millimeters (mm).

In an embodiment, each of the second light-blocking area, the third light-blocking area, and the fourth light-blocking area may have a width smaller than the width of the first light-blocking area.

In an embodiment, the light-blocking layer has a thickness equal to or greater than about 0.2 mm.

An embodiment of the inventive concept provides a method of manufacturing a display device. The manufacturing method of the display device includes placing a display panel on which a driving chip is disposed and an optical layer disposed on the display panel on a first jig, placing a second jig on the first jig and the display panel in an area adjacent to the driving chip, placing a light-blocking layer including a first light-blocking area, a second light-blocking area, a third light-blocking area, and a fourth light-blocking area on the first jig, the second jig, and the optical layer, placing a third jig to overlap the second light-blocking area and the fourth light-blocking area, providing a resin material on the optical layer and the light-blocking layer, and curing the resin material to form a coating window.

In an embodiment, the first light-blocking area of the light-blocking layer may overlap the second jig and is disposed spaced apart from the driving chip when viewed in a cross-section, and the third light-blocking area of the light-blocking layer is disposed to overlap the first jig.

In an embodiment, a plurality of first jig holes may be defined through the first jig along a thickness direction of the first jig, the light-blocking layer may include a plurality of fixing portions through which a plurality of light-blocking holes is respectively defined along a thickness direction of the light-blocking layer. The placing the light-blocking layer includes placing each of the plurality of first jig holes of the first jig and each of the plurality of light-blocking holes of the plurality of fixing portions to overlap each other.

In an embodiment, the third jig may include a plurality of protruding portions. The placing the third jig may include placing each of the plurality of protruding portions of the third jig to overlap with the plurality of light-blocking holes and the plurality of first jig holes.

In an embodiment, the method further may include irradiating a laser beam to cut the plurality of fixing portions.

In an embodiment, the plurality of fixing portions may protrude from at least two light-blocking areas among the second, third, and fourth light-blocking areas.

In an embodiment, each of the plurality of fixing portions may have a circular shape, an oval shape, or a quadrangular shape.

In an embodiment, the driving chip may be disposed spaced apart from the optical layer on the display panel. The placing the light-blocking layer may include placing the light-blocking layer to overlap with an area between the optical layer and the driving chip in a plan view. The light-blocking layer may be a rigid substrate including a light-blocking material.

In an embodiment, the providing the resin material on the optical layer and the light-blocking layer may include providing the resin material to an area overlapping an area between the driving chip and the optical layer in a plan view, and the resin material may be spaced apart from the display panel.

In an embodiment, the forming the coating window may include forming a side surface of the coating window so that the side surface of the coating window is aligned with a side surface of the light-blocking layer.

In an embodiment, the forming the coating window may include forming the coating window to cover the light-blocking layer and the optical layer.

According to the above, a lamination process is not desired to manufacture the display device including the coating window, and thus, the manufacturing process of the display device is simplified and the manufacturing cost is reduced.

According to the above, as the light-blocking layer is the rigid substrate, a deformation degree of the light-blocking layer is smaller than that of a light-blocking layer formed by a printing process. Accordingly, a bending phenomenon of the display panel, which is caused by contraction and expansion of the resin material that is cured on the display panel, is reduced or prevented.

According to the above, the side surface of the light-blocking layer, which protrudes further than the side surface of the optical layer, covers the area between the optical layer and the driving chip, a second area (e.g., a bending part) of the display panel is prevented from being perceived from the outside. In addition, the resin material is provided to an area where the light-blocking layer and the second jig are formed, and thus, the resin material is prevented from flowing to the second area of the display panel.

### BRIEF DESCRIPTION OF THE DRAWINGS

The above and other advantages of the disclosure will become readily apparent by reference to the following detailed description when considered in conjunction with the accompanying drawings, in which:

FIG. 1 is a perspective view of an embodiment of a display device according to the disclosure;

FIG. 2 is an exploded perspective view of an embodiment of a display device according to the disclosure:

FIG. 3 is a plan view of an embodiment of a display panel according to the disclosure:

FIG. 4 is a plan view of an embodiment of a light-blocking layer according to the disclosure:

FIG. 5A is a plan view of an embodiment of a display panel and a coating window according to the disclosure:

FIG. 5B is a cross-sectional view taken along line I-I′ of FIG. 5A:

FIG. 6 is a flowchart of a method of manufacturing an embodiment of a display device according to the disclosure:

FIGS. 7 to 10, and 11A are plan views of an embodiment of a method of manufacturing a display device according to the disclosure:

FIG. 11B is a cross-sectional view taken along line II-II′ of FIG. 11A:

FIG. 11C is a cross-sectional view taken along line III-III′ of FIG. 11A:

FIG. 11D is a cross-sectional view taken along line IV-IV′ of FIG. 11A:

FIG. 11E is a cross-sectional view taken along line V-V′ of FIG. 11A:

FIG. 11F is a cross-sectional view taken along line VI-VI′ of FIG. 11A:

FIG. 12 is a plan view of an embodiment of a method of manufacturing a display device according to the disclosure:

FIG. 13 is a plan view of an embodiment of a light-blocking layer according to the disclosure; and

FIG. 14 is a plan view of an embodiment of a light-blocking layer according to the disclosure.

### DETAILED DESCRIPTION

In the disclosure, it will be understood that when an element (or area, layer, or portion) is referred to as being “on”, “connected to” or “coupled to” another element or layer, it may be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” or the like, may be used herein for ease of description to describe one element or feature's relationship to another elements or features as shown in the drawing figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

The term “part” or “unit” as used herein is intended to mean a software component or a hardware component that performs a specific function. The hardware component may include a field-programmable gate array (“FPGA”) or an application-specific integrated circuit (“ASIC”), for example. The software component may refer to an executable code and/or data used by the executable code in an addressable storage medium.

Thus, the software components may be object-oriented software components, class components, and task components, for example, and may include processes, functions, attributes, procedures, subroutines, segments of program code, drivers, firmware, micro codes, circuits, data, a database, data structures, tables, arrays, or variables.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within +30%, 20%, 10%, 5% of the stated value, for example.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the disclosure will be described with reference to accompanying drawings.

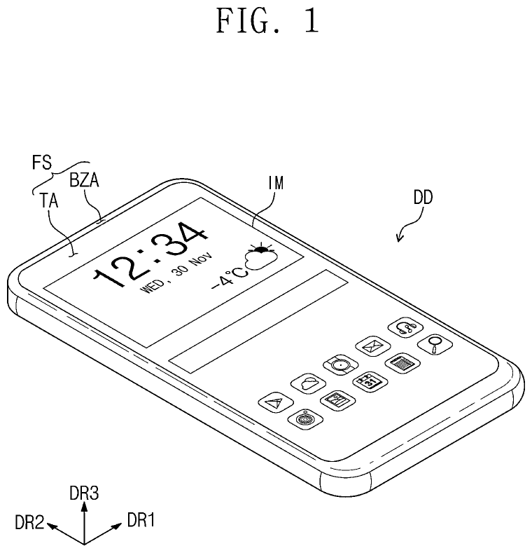

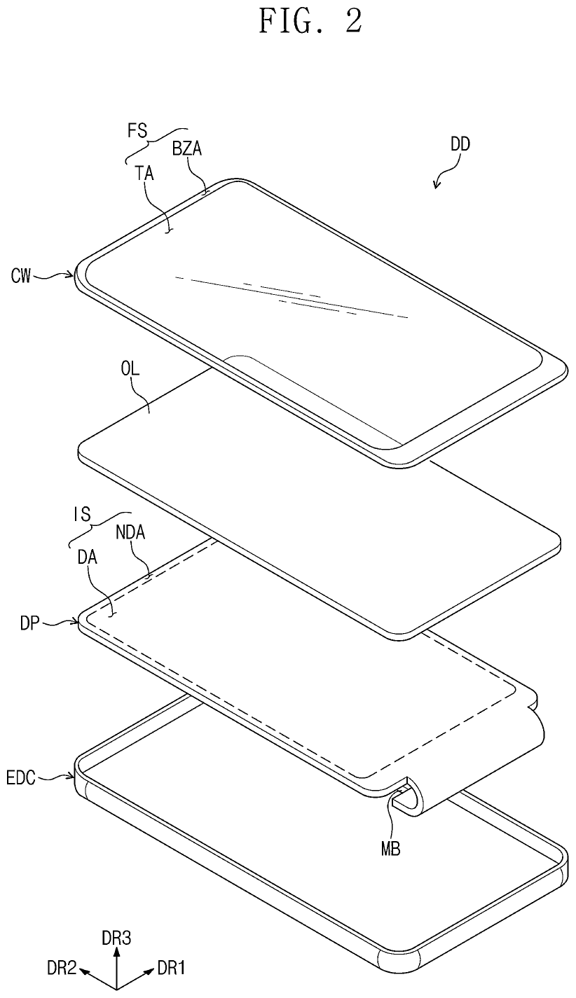

FIG. 1 is a perspective view of an embodiment of a display device DD according to the disclosure. FIG. 2 is an exploded perspective view of an embodiment of the display device DD according to the disclosure.

Referring to FIGS. 1 and 2, the display device DD may be activated in response to electrical signals and may display an image IM. In an embodiment, the display device DD may be applied to a large-sized electronic item, such as a television set or an outdoor billboard, and may be applied to a small and medium-sized electronic item, such as a monitor, a mobile phone, a tablet computer, a computer, a car navigation unit, and a game unit. However, these are merely illustrative embodiments, and the display device DD may be employed in other display devices as long as they do not deviate from the concept of the disclosure. In the illustrated embodiment, the mobile phone will be described as an illustrative embodiment of the display device DD.

Referring to FIG. 1, the display device DD may have a quadrangular shape with rounded corners, which is defined by short sides extending in a first direction DR1 and long sides extending in a second direction DR2 intersecting the first direction DR1. However, the shape of the display device DD should not be limited to the rectangular shape, and the display device DD may have a variety of shapes, such as a quadrangle shape (for example, a square shape), a circular shape, a polygonal shape, or an irregular shape in a plan view:

The display device DD of the disclosure may be flexible. The term “flexible” used herein refers to the property of being able to be bent from a structure that is completely bent to a structure that is bent at the scale of a few nanometers. In an embodiment, the flexible display device DD may be a curved display device, a foldable display device, a slidable display device, or a rollable display device, for example, however, the disclosure should not be limited thereto or thereby. In an embodiment, the display device DD may be rigid.

The display device DD may display the image IM through a display surface toward a third direction DR3 substantially perpendicular to a plane defined by the first direction DR1 and the second direction DR2. The image IM provided from the display device DD may include a still image as well as a video. FIG. 1 shows a clock widget and application icons as an illustrative embodiment of the image IM. The display surface through which the image IM is displayed may correspond to a front surface of the display device DD and a front surface FS of a coating window CW. FIG. 1 shows a flat display surface as an illustrative embodiment, however, in an embodiment, the display surface of the display device DD may have a curved shape bent from at least one side of the plane.

Front (or upper) and rear (or lower) surfaces of each member of the display device DD may be opposite to each other in the third direction DR3, and a normal line direction of each of the front and rear surfaces may be substantially parallel to the third direction DR3. A separation distance between the front and rear surfaces of each member (or each unit) in the third direction DR3 may correspond to a thickness of the member (or the unit) in the third direction DR3. In the disclosure, the expression “in a plan view” may mean a state of being viewed in the third direction DR3. In the disclosure, the expression “in a cross-section” may mean a state of being viewed in the first direction DR1 or the second direction DR2. Directions indicated by the first, second, and third directions DR1, DR2, and DR3 may be relative to each other, and thus, the directions indicated by the first, second, and third directions DR1, DR2, and DR3 may be changed to other directions.

Referring to FIG. 2, the display device DD may include the coating window CW, an optical layer OL, a display panel DP, and a case EDC. The coating window CW may be coupled with the case EDC to form an external appearance of the display device DD.

The coating window CW may be disposed on the display panel DP. The coating window CW may have a shape corresponding to a shape of the display panel DP. The coating window CW may cover an entirety of the external surface of the display panel DP and may protect the display panel DP from external impacts and scratches.

The coating window CW may include an optically transparent insulating material. In an embodiment, the coating window CW may include a resin material. The coating window CW may have a single-layer or multi-layer structure. The coating window CW may further include functional layers, such as an anti-fingerprint layer, a phase control layer, a hard coating layer, etc., disposed on an optically transparent substrate. In a method of manufacturing the display device DD including the coating window CW according to the disclosure, a lamination process may be omitted. Accordingly, the manufacturing method of the display device DD may be simplified, and a manufacturing cost of the display device DD may be reduced.

The front surface FS of the coating window CW may include a transmission area TA and a bezel area BZA. The transmission area TA of the coating window CW may be an optically transparent area. Accordingly, the coating window CW may transmit the image IM provided from the display panel DP through the transmission area TA, and the user US may view the image IM.

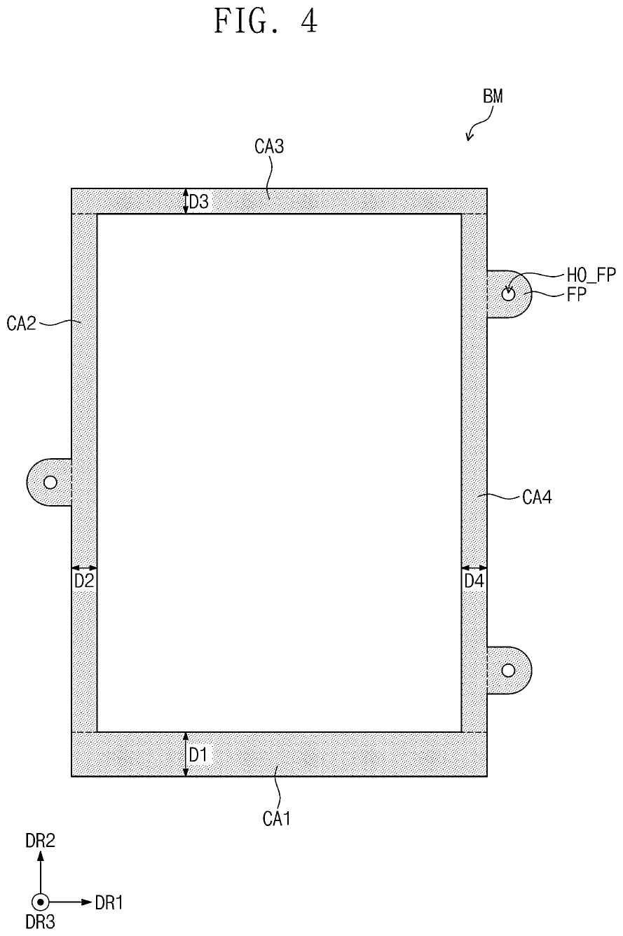

The bezel area BZA of the coating window CW may overlap a light-blocking layer BM (refer to FIG. 4) described later. The light-blocking layer BM may be a rigid substrate including a material having a predetermined color. The bezel area BZA of the coating window CW may prevent components of the display panel DP, which are disposed to overlap the bezel area BZA, from being viewed from the outside.

The bezel area BZA may be defined adjacent to the transmission area TA, and the shape of the transmission area TA may be defined by the bezel area BZA. In an embodiment, the bezel area BZA may be disposed outside the transmission area TA and may surround the transmission area TA, however, it should not be limited thereto or thereby. The bezel area BZA may be defined adjacent to only one side of the transmission area TA or may be omitted. In addition, the bezel area BZA may be defined at a side surface of the display device DD rather than the front surface of the display device DD.

The optical layer OL may be disposed between the display panel DP and the coating window CW. The optical layer OL may reduce a reflectance with respect to a light incident thereto from the outside. The optical layer OL may include a retarder and/or a polarizer. The optical layer OL may include at least a polarizing film. In this case, the optical layer OL may be attached to the display panel DP by an adhesive layer, however, the disclosure should not be limited thereto or thereby. In an embodiment, the optical layer OL may include color filters, for example.

The display panel DP may be disposed between the coating window CW and the case EDC. The display panel DP may display the image IM in response to the electrical signals. In an embodiment, the display panel DP may be a light-emitting type display panel, however, it should not be particularly limited. In an embodiment, the display panel DP may be an organic light-emitting display panel, an inorganic light-emitting display panel, an organic-inorganic light-emitting display panel, or a quantum dot light-emitting display panel. A light-emitting layer of the organic light-emitting display panel may include an organic light-emitting material. A light-emitting layer of the inorganic light-emitting display panel may include an inorganic light-emitting material. A light-emitting layer of the organic-inorganic light-emitting display panel may include an organic-inorganic light-emitting material. A light-emitting layer of the quantum dot light-emitting display panel may include a quantum dot or a quantum rod.

The image IM provided by the display device DD may be displayed through a front surface IS of the display panel DP. The front surface IS of the display panel DP may include a display area DA and a non-display area NDA. The display area DA of the display panel DP may be activated in response to electrical signals, and the image IM may be displayed through the display area DA. In an embodiment, the display area DA of the display panel DP may correspond to the transmission area TA of the coating window CW. In the following descriptions, the expression “An area/portion corresponds to another area/portion.” means that “An area/portion overlaps another area/portion.”, however, they should not be limited to having the same size or the same shape.

The non-display area NDA may be defined adjacent to an outer side of the display area DA. In an embodiment, the non-display area NDA may surround the display area DA. However, it should not be limited thereto or thereby, and the non-display area NDA may be defined in a variety of shapes.

A driving circuit or a driving line to drive elements arranged in the display area DA, various signal lines to provide electrical signals, and pads may be disposed in the non-display area NDA. The non-display area NDA of the display panel DP may correspond to the bezel area BZA of the coating window CW. Components of the display panel DP, which are disposed in the non-display area NDA, may be prevented from being viewed from the outside by the bezel area BZA.

The display device DD may include a circuit board MB connected to the display panel DP. The circuit board MB may be connected to one end of the display panel DP extending in the first direction DR1. The circuit board MB may generate electrical signals provided to the display panel DP. In an embodiment, the circuit board MB may include a timing controller that generates signals provided to a driver of the display panel DP in response to control signals applied thereto from the outside.

At least a portion of the non-display area NDA of the display panel DP may be bent. A portion of the display panel DP, which is connected to the circuit board MB, may be bent to allow the circuit board MB to face a rear surface of the display panel DP. The circuit board MB may be disposed to overlap the rear surface of the display panel DP and may be coupled with the display panel DP, however, the disclosure should not be limited thereto or thereby. In an embodiment, the display panel DP and the circuit board MB may be connected to each other via a flexible circuit board connected to ends of the display panel DP and the circuit board MB.

The case EDC may provide an inner space in which components of the display device DD are accommodated. The case EDC may be disposed under the display panel DP and may accommodate the display panel DP. The case EDC may include a glass, plastic, or metal material with a relatively high strength. The case EDC may absorb impacts applied thereto from the outside and may prevent a foreign substance and moisture from entering the display panel DP to protect the display panel DP.

The display device DD may further include an input sensing layer disposed on the display panel DP and sensing an external input applied thereto from the outside. The input sensing layer may sense the external input provided in various forms, such as force, pressure, temperature, or light In an embodiment, the input sensing layer may sense a contact through a user's body part or a pen provided from the outside of the display device DD or a non-contact input (e.g., hovering) applied when approaching close to the display device DD.

In addition, the display device DD may further include an electronic module including a variety of functional modules to drive the display panel DP and a power supply module supplying a power desired for an overall operation of the display device DD. In an embodiment, the display device DD may include a camera module as an illustrative embodiment of the electronic module, for example.

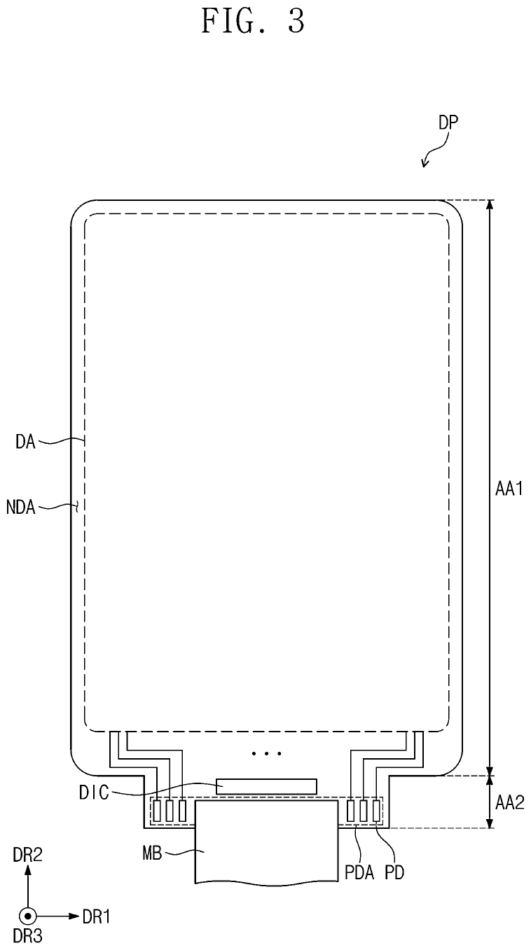

FIG. 3 is a plan view of an embodiment of the display panel DP according to the disclosure.

Referring to FIG. 3, the display panel DP may include a first area AA1 and a second area AA2. The first area AA1 may correspond to a display part of the display panel DP, and the second area AA2 may correspond to a bending part of the display panel DP.

The first area AA1 may include the display area DA and a portion of the non-display area NDA defined adjacent to the display area DA. The second area AA2 may include the other portion of the non-display area NDA. The second area AA2 may extend from the first area AA1. In an embodiment, the second area AA2 may extend from the first area AA1 to a direction opposite to the second direction DR2.

The second area AA2 may include a pad area PDA. A plurality of pads PD may be arranged in the pad area PDA. The pads PD may be arranged spaced apart from each other in the first direction DR1. In addition, a driving chip DIC may be disposed in the second area AA2. The pads PD may be electrically connected to the driving chip DIC and circuit lines extending from the first area AA1. Some of the pads PD may be provided to connect the circuit board MB to the display panel DP. The pads PD may be connected to corresponding pixels via the circuit lines extending from the first area AA1. The second area AA2 to which the circuit board MB is connected may be bent toward a rear surface of the first area AA1.

FIG. 4 is a plan view of an embodiment of the light-blocking layer BM according to the disclosure.

Referring to FIGS. 3 and 4, the light-blocking layer BM may be a rigid substrate including a light-blocking material. A degree of deformation of the light-blocking layer BM may be smaller than that of the light-blocking layer formed by a printing process. Accordingly, a bending phenomenon of the display panel DP, which is caused by contraction and expansion of the resin material that is cured on the display panel DP, may be reduced or prevented.

The light-blocking layer BM may be disposed to overlap the non-display area NDA of the display panel DP. The light-blocking layer may have a thickness equal to or greater than about 0.2 millimeter (mm). The light-blocking layer BM may include a first light-blocking area CA1, a second light-blocking area CA2, a third light-blocking area CA3, and a fourth light-blocking area CA4.

The first light-blocking area CA1 may be disposed adjacent to the area in which the driving chip DIC of the display panel DP is disposed. The second light-blocking area CA2 and the fourth light-blocking area CA4 may extend from the first light-blocking area CA1 to the second direction DR2. The second light-blocking area CA2 and the fourth light-blocking area CA4 may face each other and may be spaced apart from each other in the first direction DR1. The third light-blocking area CA3 may extend to the second light-blocking area CA2 and the fourth light-blocking area CA4 and may face the first light-blocking area CA1. The first light-blocking area CA1 and the third light-blocking area CA3 may be disposed spaced apart from each other in the second direction DR2.

The second light-blocking area CA2, the third light-blocking area CA3, and the fourth light-blocking area CA4 may respectively have widths D2, D3, and D4 smaller than a width D1 of the first light-blocking area CA1. In an embodiment, the width D1 of the first light-blocking area CA1 may be equal to or greater than about 2 mm, and each of the widths D2, D3, and D4 of the second light-blocking area CA2, the third light-blocking area CA3, and the fourth light-blocking area CA4 may be about 1.5 mm.

The light-blocking layer BM may further include a plurality of fixing portions FP. The fixing portions FP may be used to fix the light-blocking layer BM to a predetermined position during the manufacturing process of the display panel. A light-blocking hole HO_FP may be defined through each of the fixing portions FP along a thickness direction of the light-blocking layer BM, e.g., the third direction DR3. The fixing portions FP may protrude from at least two light-blocking areas among the second light-blocking area CA2, the third light-blocking area CA3, and the fourth light-blocking area CA4. The fixing portions FP may have a circular shape, an oval shape, or a quadrangular shape.

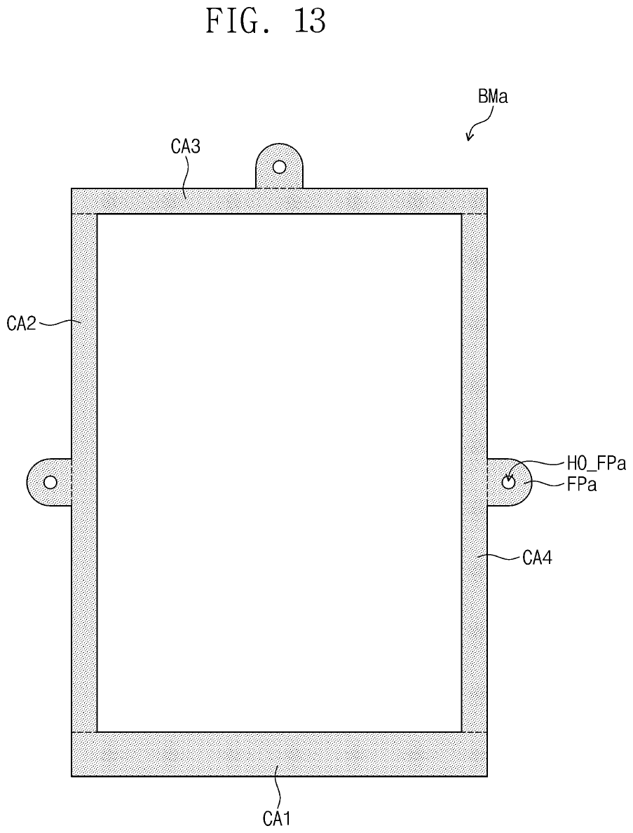

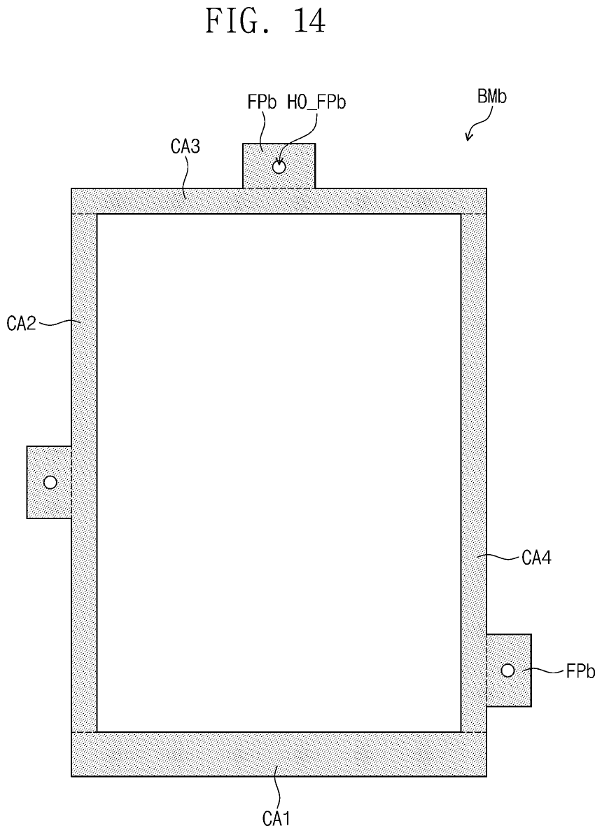

The position, shape, and number of the fixing portions FP are merely illustrative embodiments and should not be particularly limited as long as they do not depart from the concept of the disclosure. FIG. 4 shows one fixing portion FP protruded from the second light-blocking area CA2 and two fixing portions FP protruded from the fourth light-blocking area CA4 as an illustrative embodiment, however, the disclosure should not be limited thereto or thereby. In addition, the fixing portions FP having the circular shape are shown in FIG. 4, however, they should not be limited thereto or thereby. The fixing portions FP will be described in detail with reference to FIGS. 13 and 14.

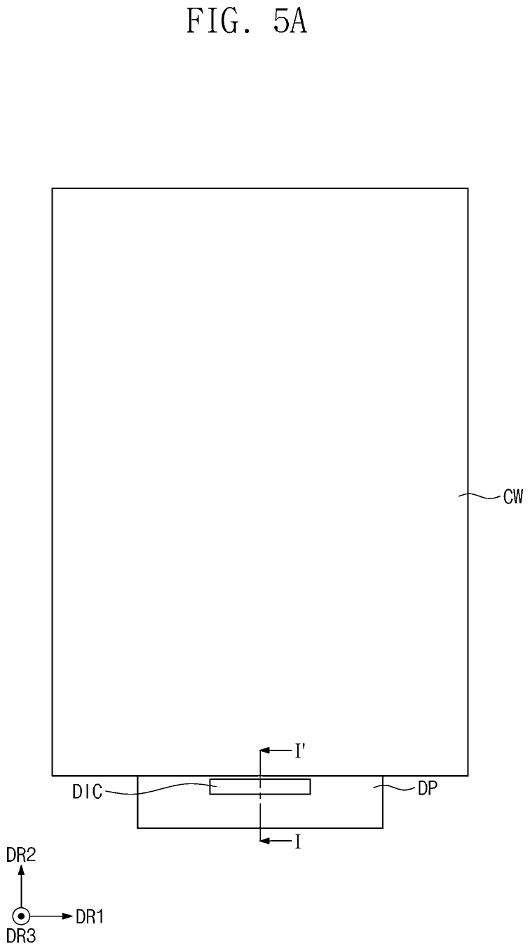

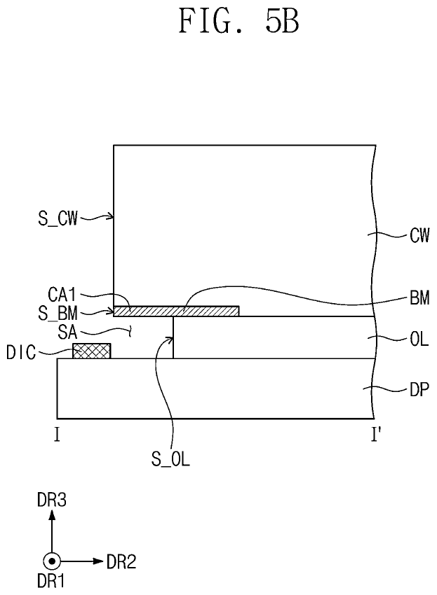

FIG. 5A is a plan view of an embodiment of the display panel DP and the coating window CW according to the disclosure. FIG. 5B is a cross-sectional view taken along line I-I′ of FIG. 5A.

Referring to FIGS. 5A and 5B, the driving chip DIC may be disposed on the display panel DP, and the driving chip DIC may be disposed spaced apart from the optical layer OL in the plan view. The light-blocking layer BM may be disposed on the optical layer OL. In detail, a portion of the light-blocking layer BM may overlap the optical layer OL.

The light-blocking layer BM may include at least one side surface S_BM. When viewed in a cross-section, the side surface S_BM of the light-blocking layer BM may protrude further than a side surface S_OL of the optical layer OL. In an embodiment, the first light-blocking area CAL of the light-blocking layer BM may include the side surface S_BM that protrudes further than the side surface S_OL of the optical layer OL, however, this is merely one of embodiments. In an embodiment, each of the second light-blocking area CA2, the third light-blocking area CA3, and the fourth light-blocking area CA4 of the light-blocking layer BM may include the side surface S_BM that protrudes further than the side surface S_OL of the optical layer OL. In the plan view, the light-blocking layer BM may be disposed to overlap an area SA between the optical layer OL and the driving chip DIC. The area SA may be also referred to as a space, a separation area, a separation space, an interspace, an interzone, or an intermediate area.

The coating window CW may be disposed on the optical layer OL and the light-blocking layer BM. The coating window CW may include a side surface S_CW aligned with the side surface S_BM of the light-blocking layer BM. Portions of the light-blocking layer BM and the coating window CW, which protrude further than the side surface S_OL of the optical layer OL, may cover an area overlapping the area SA between the optical layer OL and the driving chip DIC. Accordingly, the light-blocking layer BM may prevent the second area AA2 (refer to FIG. 3) of the display panel DP from being perceived from the outside.

The coating window CW may cover the light-blocking layer BM and the optical layer OL. In an embodiment, the coating window CW may cover a front surface of the light-blocking layer BM and the optical layer OL. The coating window CW may include the resin material. The coating window CW may be formed by curing the resin material.

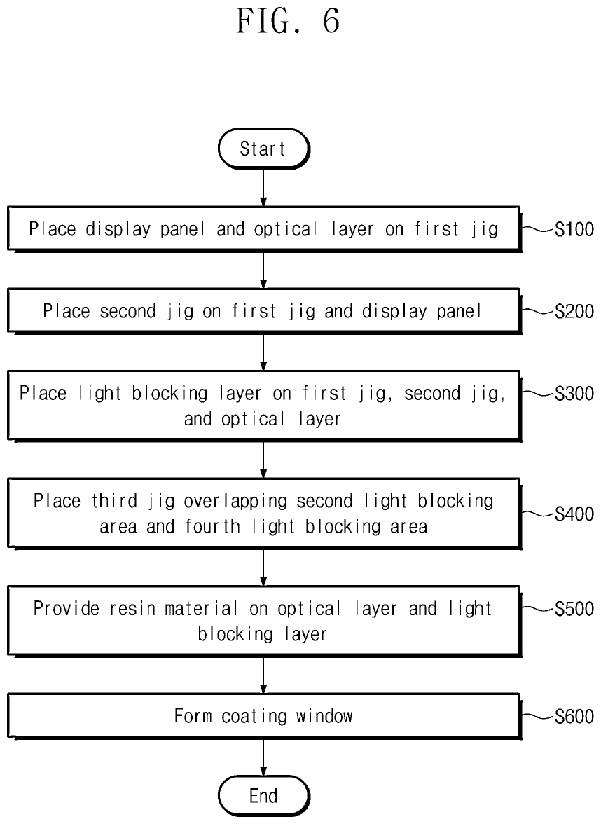

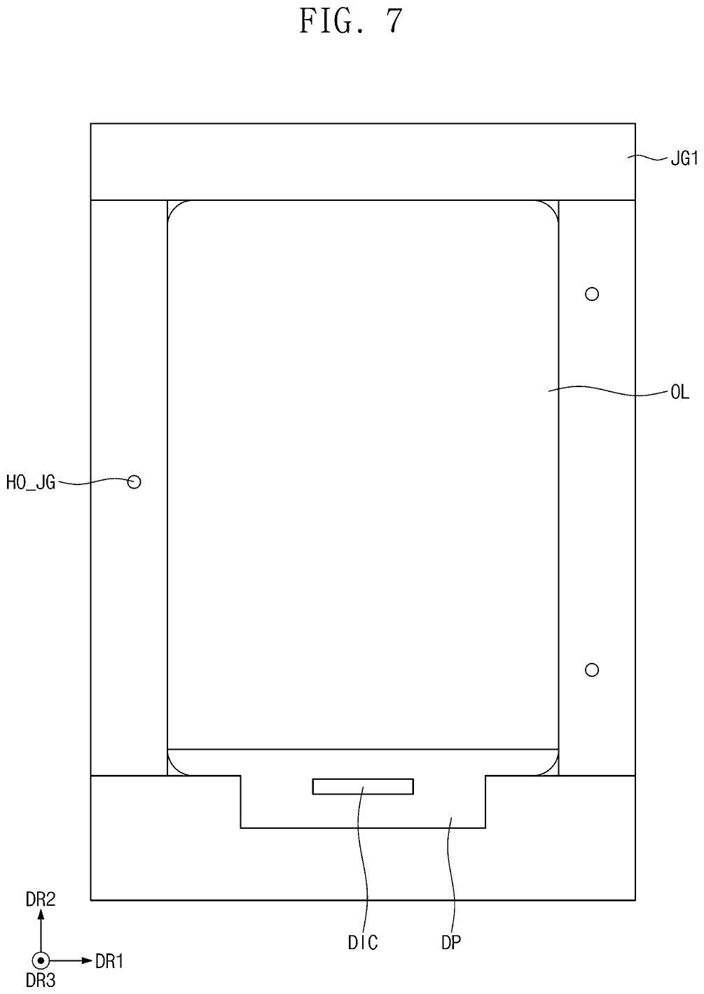

FIG. 6 is a flowchart of an embodiment of a method of manufacturing the display device according to the disclosure. FIGS. 7 to 10, 11A, and 12 are plan views of an embodiment of the manufacturing method of the display device according to the disclosure. In FIGS. 6 to 10, 11A, and 12, the same reference numerals denote the same elements in FIGS. 1 to 5, and thus, detailed descriptions of the same elements will be omitted.

The manufacturing method of the display device may include placing the display panel on which the driving chip is disposed and the optical layer disposed on the display panel on a first jig (S100), placing a second jig on the first jig and the display panel in the area adjacent to the driving chip (S200), placing the light-blocking layer including the first light-blocking area, the second light-blocking area, the third light-blocking area, and the fourth light-blocking area on the optical layer and the second jig (S300), placing a third jig to overlap the second light-blocking area and the fourth light-blocking area (S400), providing the resin material on the optical layer and the light-blocking layer (S500), and curing the resin material to form the coating window (S600).

Referring to FIGS. 6 and 7, the display panel DP and the optical layer OL disposed on the display panel DP may be disposed on the first jig JG1 (S100). The first jig JG1 may be a lower jig. A concave groove may be defined in a center portion of the first jig JG1. The display panel DP and the optical layer OL may be disposed in the concave groove of the first jig JG1. The driving chip DIC may be disposed on the display panel DP. In an embodiment, the driving chip DIC may be disposed on the display panel DP and may be spaced apart from the optical layer OL.

Portions of the display panel DP and the optical layer OL may be disposed to contact inner side surfaces that define the concave groove of the first jig JG1. In an embodiment, the inner side surface of the first jig JG1, which is adjacent to the area in which the driving chip DIC is disposed, may contact a side surface of the display panel DP, and the inner side surfaces of the first jig JG1, which is spaced apart from the area in which the driving chip DIC is disposed, may contact the side surface of the display panel DP and a side surface of the optical layer OL.

A plurality of first jig holes HO_JG may be defined through the first jig JG1 along a thickness direction of the first jig JG1, e.g., the third direction DR3. The first jig holes HO_JG may be holes in which a protruding portion PP of the second jig JG2 described later is disposed.

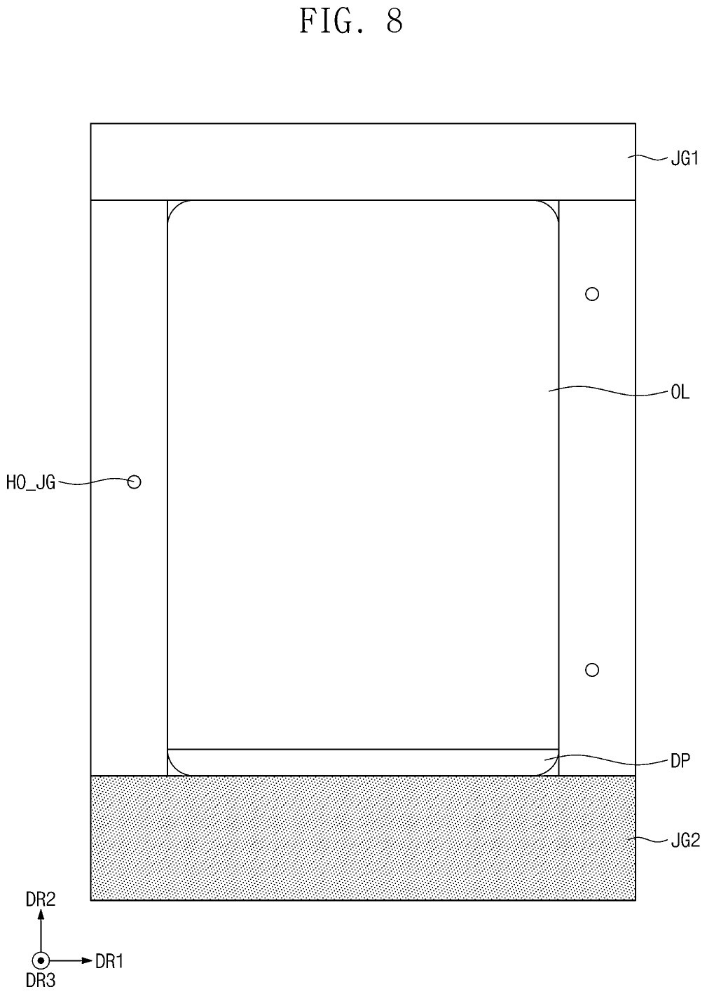

Referring to FIGS. 6 and 8, the second jig JG2 may be disposed (S200). The second jig JG2 may be disposed on the first jig JG1 and the display panel DP in the area adjacent to the driving chip DIC. In an embodiment, the second jig JG2 may cover the second area AA2 (refer to FIG. 3) of the display panel DP in the plan view.

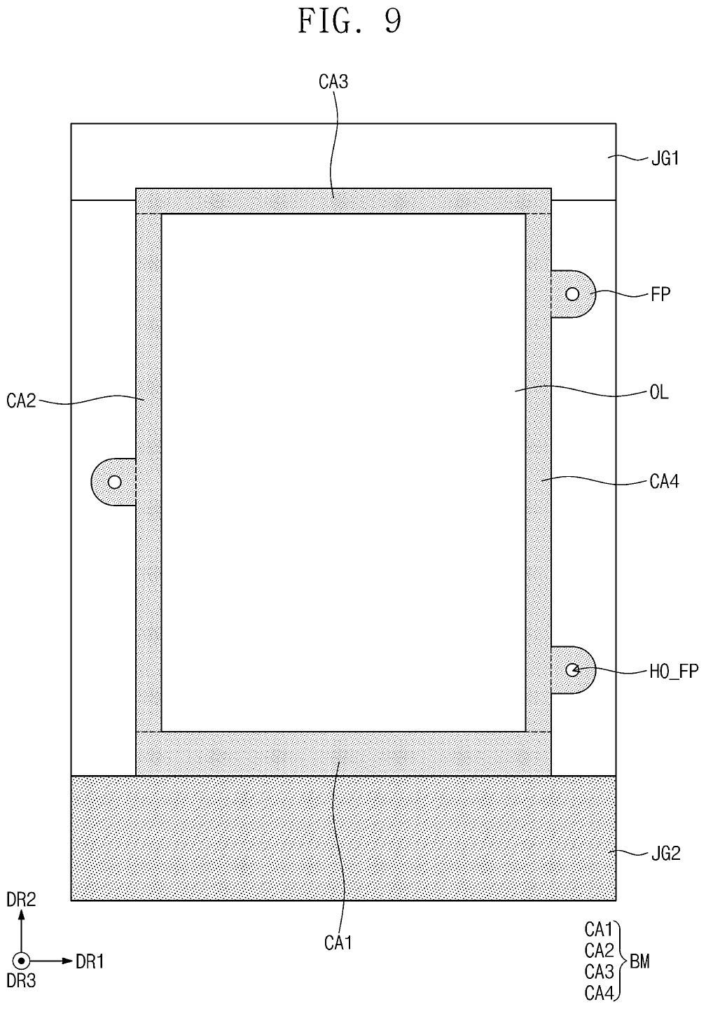

Referring to FIGS. 6 and 9, the light-blocking layer BM may be disposed on the first jig JG1, the second jig JG2, and the optical layer OL (S300). The light-blocking layer BM may be the rigid substrate including the light-blocking material. A portion of the first light-blocking area CAL may overlap the second jig JG2 and may be spaced apart from the driving chip DIC when viewed in the cross-section. The third light-blocking area CA3 may be disposed to overlap the first jig JG1.

The light-blocking layer BM may further include the fixing portions FP. The light-blocking hole HO_FP may be defined through each of the fixing portions FP along the thickness direction of the light-blocking layer BM, e.g., the third direction DR3. The fixing portions FP may protrude from at least two light-blocking areas among the second light-blocking area CA2, the third light-blocking area CA3, and the fourth light-blocking area CA4. Each of the fixing portions FP may have various shapes such as a circular, oval, or quadrangular shape.

The placing of the light-blocking layer BM may include placing the first jig JG1 and the fixing portions FP such that the first jig holes HO_JG of the first jig JG1 respectively overlap the light-blocking holes HO_FP of the fixing portions FP. That is, one first jig hole HO_JG among the first jig holes HO_JG may overlap one light-blocking hole HO_FP among the light-blocking holes HO_FP.

In addition, the light-blocking layer BM may be disposed to overlap the area SA (refer to FIG. 5B) between the optical layer OL and the driving chip DIC in the plan view.

That is, the portion of the light-blocking layer BM, which protrudes further e than the side surface S_OL (refer to FIG. 5B) of the optical layer OL, may cover the area SA between the optical layer OL and the driving chip DIC.

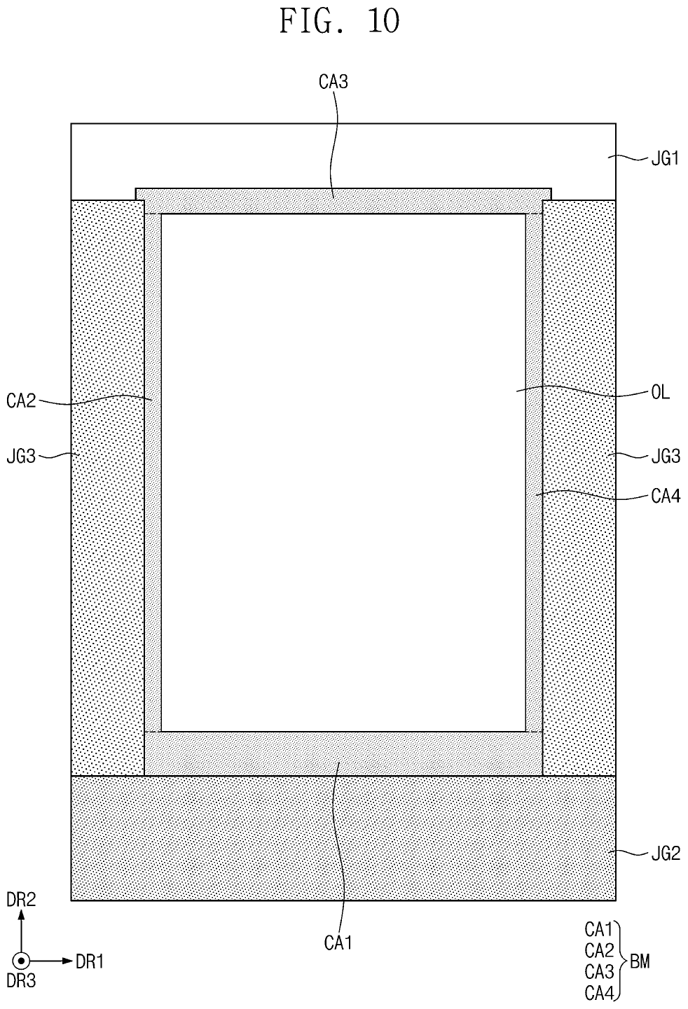

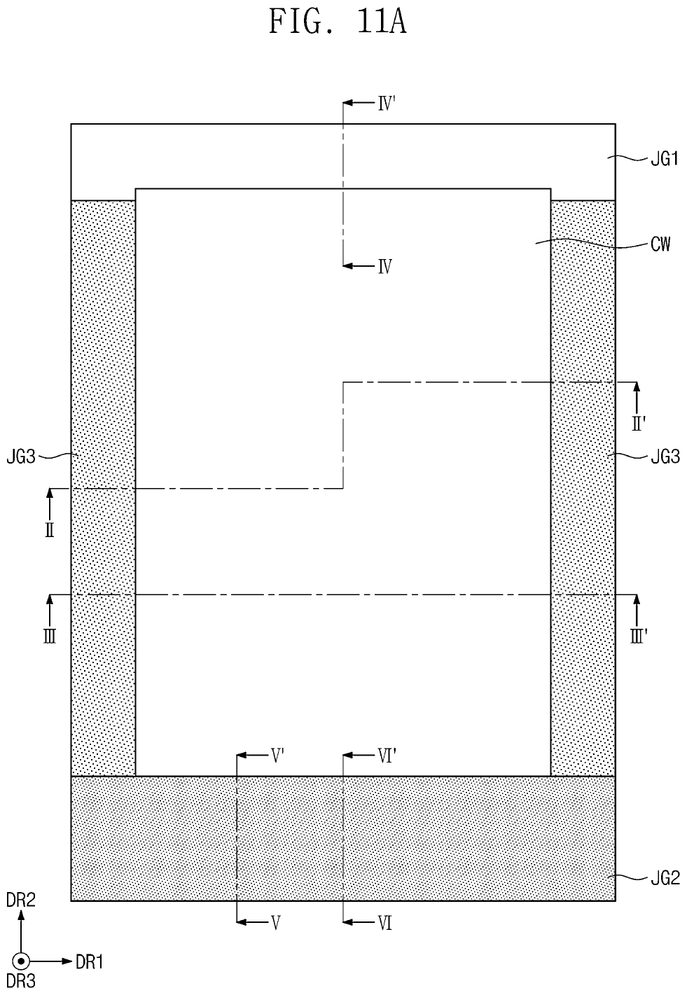

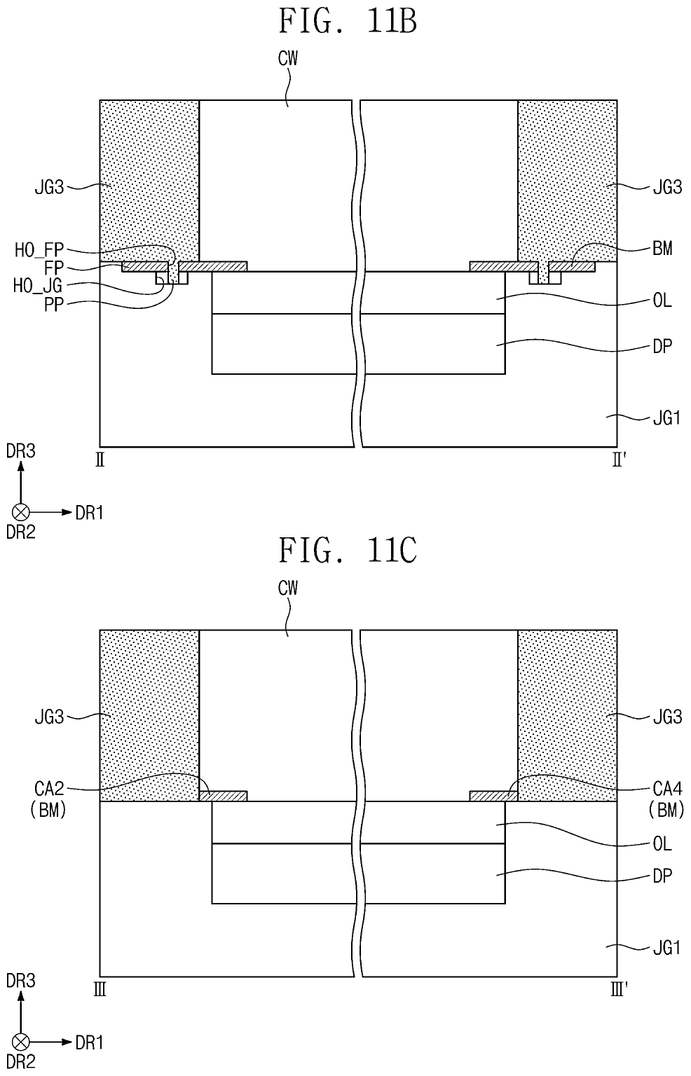

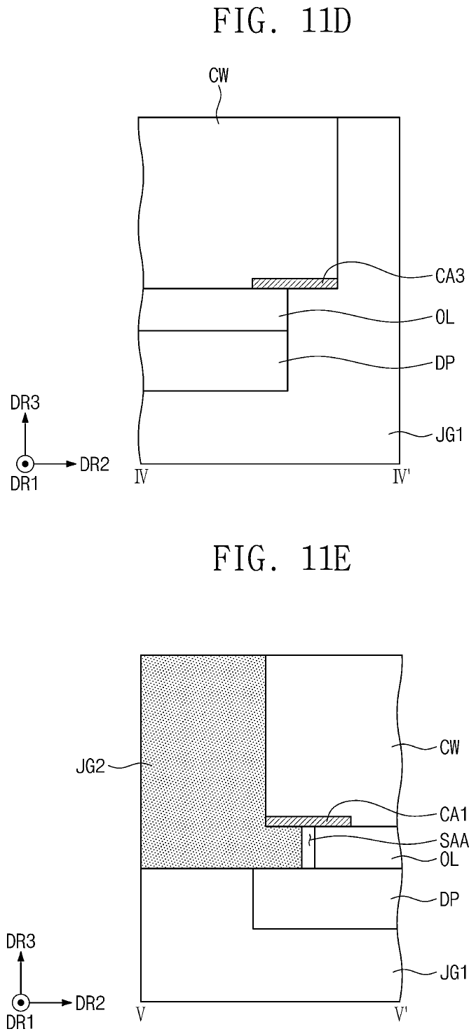

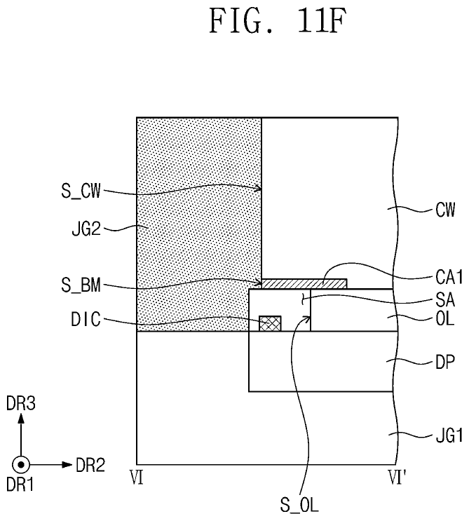

Referring to FIGS. 6 and 10, the third jig JG3 may be disposed on the light-blocking layer BM and the first jig JG1 (S400). The third jig JG3 may be disposed to overlap the second light-blocking area CA2 and the fourth light-blocking area CA4 of the light-blocking layer BM. The third jig JG3 may include a plurality of protruding portions PP (refer to FIG. 11B). The protruding portions PP may protrude from a lower surface of the third jig JG3 to a direction opposite to the third direction DR3. The third jig JG3 may be disposed to allow the protruding portions PP of the third jig JG3 to overlap the light-blocking holes HO_FP (refer to FIG. 11B) and the first jig holes HO_JG (refer to FIG. 11B). In an embodiment, one protruding portion PP among the protruding portions PP may be disposed in one light-blocking hole HO_FP among the light-blocking holes HO_FP and one first jig hole HO_JG among the first jig holes HO_JG. The protruding portions PP of the third jig JG3 may fix the light-blocking layer BM to a predetermined position, and thus, the light-blocking layer BM that is not adhered with an adhesive layer may be aligned at a predetermined position on the display panel DP and the optical layer OL.

Referring to FIGS. 6 and 11A, the resin material may be provided on the optical layer OL and the light-blocking layer BM (S500), and the resin material may be cured to form the coating window CW (S600).

The resin material provided on the optical layer OL and the light-blocking layer BM may be provided to the area overlapping the area SA (refer to FIG. 11F) between the driving chip DIC and the optical layer OL in the plan view. The resin material may be provided to be spaced apart from the area SA. The resin material may be provided to a space defined by the first jig JG1, the second jig JG2, and the third jig JG3.

The coating window CW may be formed to cover the light-blocking layer BM and the optical layer OL. Since the resin material is provided on the light-blocking layer BM and the optical layer OL and is cured in the space defined by the first jig JG1, the second jig JG2, and the third jig JG3, the coating window CW may cover the light-blocking layer BM and the optical layer OL.

FIG. 11B is a cross-sectional view taken along line II-II′ of FIG. 11A. FIG. 11B is a cross-sectional view of a portion where the fixing portions FP of the light-blocking layer BM (refer to FIG. 11A) are disposed.

Referring to FIGS. 11A and 11B, the display panel DP and the optical layer OL may be disposed on the first jig JG1. In an embodiment, the display panel DP and the optical layer OL may be disposed in the concave groove of the first jig JG1. The protruding portions PP of the third jig JG3 may be disposed to overlap the light-blocking holes HO_FP and the first jig holes HO_JG and may fix the light-blocking layer BM to the predetermined position. The coating window CW may be disposed on the optical layer OL and the light-blocking layer BM and may cover the portions of the optical layer OL and the light-blocking layer BM. When viewed in the cross-section, the portion of the light-blocking layer BM, which protrudes further than the coating window CW, may be removed later in a laser cutting process.

FIG. 11C is a cross-sectional view taken along line III-III′ of FIG. 11A. FIG. 11C is a cross-sectional view of a portion where the fixing portions FP of the light-blocking layer BM are not disposed.

Referring to FIGS. 11A and 11C, the display panel DP and the optical layer OL may be disposed on the first jig JG1. In an embodiment, the display panel DP and the optical layer OL may be disposed in the concave groove of the first jig JG1. The light-blocking layer BM may be disposed on the first jig JG1 and the optical layer OL, and the third jig JG3 may be disposed not to overlap the light-blocking layer BM. The coating window CW may be formed on the optical layer OL and the light-blocking layer BM. The coating window CW may be formed along a side surface of the third jig JG3, and the side surface of the coating window CW may be aligned with an outer side surface of the second and fourth light-blocking areas CA2 and CA4.

FIG. 11D is a cross-sectional view taken along line IV-IV′ of FIG. 11A. FIG. 11D is a cross-sectional view of a portion where the upper jig, e.g., the second and third jigs JG2 and JG3, are not disposed.

Referring to FIGS. 11A and 11D, the display panel DP and the optical layer OL may be disposed on the first jig JG1. In an embodiment, the display panel DP and the optical layer OL may be disposed in the concave groove of the first jig JG1. The third light-blocking area CA3 of the light-blocking layer BM may be disposed on the optical layer OL and the first jig JG1, and the coating window CW may be disposed on the optical layer OL and the light-blocking layer BM. The coating window CW may be formed along a side surface of the first jig JG1, and the side surface of the coating window CW may be aligned with an outer side surface of the third light-blocking area CA3.

FIG. 11E is a cross-sectional view taken along line V-V′ of FIG. 11A. FIG. 11E is a cross-sectional view of a portion where the second jig JG2 is disposed but the driving chip DIC (refer to FIG. 11A) is not disposed.

Referring to FIGS. 11A and 11E, the display panel DP and the optical layer OL may be disposed on the first jig JG1. In an embodiment, the display panel DP may be disposed in the concave groove of the first jig JG1. A portion of the second jig JG2 may be disposed on the first jig JG1 and the display panel DP. The portion of the second jig JG2, which is disposed on the display panel DP, may have substantially the same thickness as that of the optical layer OL. The portion of the second jig JG2 adjacent to the optical layer OL may be disposed spaced apart from the optical layer OL.

An area (or a space) SAA between the optical layer OL and the second jig JG2 may be a process margin to prevent the display panel DP and the optical layer OL from being damaged when the display panel DP and the optical layer OL are disposed in the first, second, and third jigs JG1, JG2, and JG3.

The light-blocking layer BM may be disposed on the second jig JG2 and the optical layer OL, and the coating window CW may be formed on the optical layer OL and the light-blocking layer BM. The coating window CW may be formed along a side surface of the second jig JG2, and the side surface of the coating window CW may be aligned with an outer side surface of the first light-blocking area CA1.

FIG. 11F is a cross-sectional view taken along line VI-VI′ of FIG. 11A. FIG. 11F is a cross-sectional view of a portion where the second jig JG2 is disposed and the driving chip DIC (refer to FIG. 11A) is disposed.

Referring to FIGS. 11A and 11F, the display panel DP and the optical layer OL may be disposed on the first jig JG1. In an embodiment, the display panel DP may be disposed in the concave groove of the first jig JG1. A portion of the second jig JG2 may be disposed on the first jig JG1. The portion of the second jig JG2 may be disposed spaced apart from the optical layer OL.

The light-blocking layer BM may be disposed on the optical layer OL. In detail, the light-blocking layer BM may be disposed to overlap the area SA between the optical layer OL and the driving chip DIC. Referring to FIG. 11F, the portion of the second jig JG2, which faces the area where the driving chip DIC is disposed, does not support the light-blocking layer BM, however, referring to FIG. 11E, the portion of the second jig JG2 facing the area where the driving chip DIC is not disposed may protrude and thus may support the light-blocking layer BM. Since the portion of the second jig JG2 supports the light-blocking layer BM, a more stable structure may be provided in the process of forming the coating window CW. In addition, since the light-blocking layer BM is the rigid substrate, the shape of the light-blocking layer BM may be maintained.

The coating window CW may be formed on the optical layer OL and the light-blocking layer BM. Since the light-blocking layer BM is disposed spaced apart from the driving chip DIC in the cross-section, the coating window CW may be formed spaced apart from the driving chip DIC. The coating window CW may be formed along the side surface of the second jig JG2, and the side surface of the coating window CW may be aligned with the outer side surface of the first light-blocking area CA1.

Referring to FIGS. 11A to 11F, since the light-blocking layer BM is the rigid substrate, the degree of deformation of the light-blocking layer BM may be smaller than that of the light-blocking layer formed by the printing process. Accordingly, the bending phenomenon of the display panel DP, which is caused by the contraction and expansion of the resin material that is cured on the display panel DP, may be reduced or prevented.

In addition, since the light-blocking layer BM that protrudes further than the side surface S_OL of the optical layer OL covers the area overlapping the area SA between the optical layer OL and the driving chip DIC, the second area AA2 (refer to FIG. 3) of the display panel DP may be prevented from being perceived from the outside. Further, as the resin material is provided in the area where the light-blocking layer BM and the second jig JG2 are formed, the resin material may be prevented from flowing through the second area AA2 of the display panel DP.

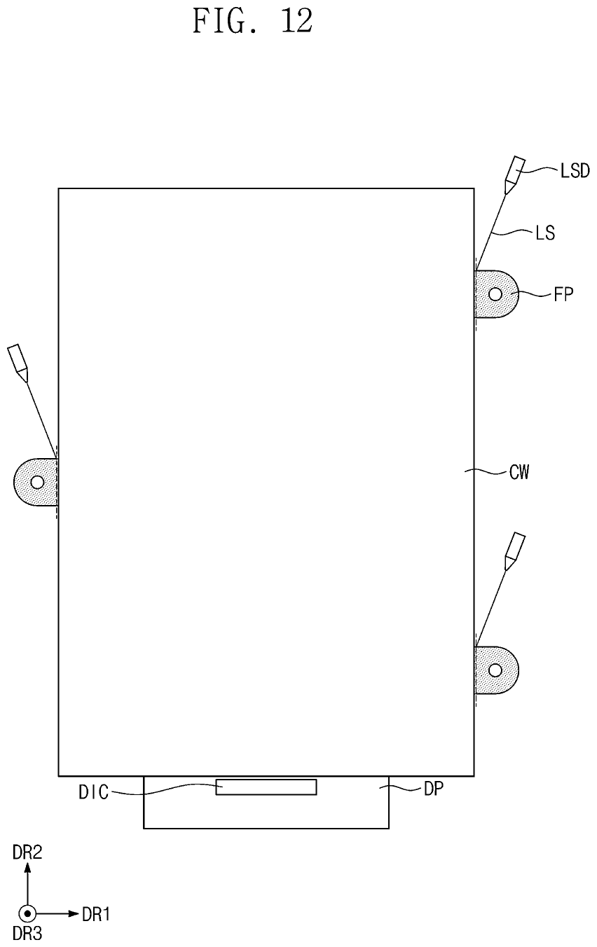

Referring to FIGS. 6 and 12, the manufacturing method of the display device may further include cutting the fixing portions FP. A laser beam LS may be irradiated to areas between the fixing portions FP and at least two light-blocking areas among the second light-blocking area CA2, the third light-blocking area CA3, and the fourth light-blocking area CA4 using a laser device LSD. The fixing portions FP protruded from the light-blocking areas CA2, CA3, and CA4 may be cut by the irradiated laser beam LS. As the portion of the light-blocking layer BM, which protrudes further than the coating window CW in FIG. 11B, is cut, the side surface of the coating window CW may be aligned with the outer side surfaces of the second and fourth light-blocking areas CA2 and CA4.

FIG. 12 shows a process in which the fixing portions FP are respectively cut using three laser devices LSD as an illustrative embodiment, however, the disclosure should not be limited thereto or thereby. In an embodiment, a single laser device LSD may cut the fixing portions FP while moving.

Referring to FIGS. 11A to 12, the forming of the coating window CW may include forming the side surface of the coating window CW to be aligned with the side surface of the light-blocking layer BM. The side surfaces of the coating window CW may be aligned with the side surfaces of the first, second, third, and fourth light-blocking areas CA1, CA2, CA3, and CA4.

The manufacturing method of the display device may further include curing the coating window CW. The curing of the coating window CW may be performed before the cutting of the fixing portions FP or after the cutting of the fixing portions FP.

FIG. 13 is a plan view of an embodiment of a light-blocking layer BMa according to the disclosure. In FIG. 13, the same reference numerals denote the same elements in FIG. 4, and thus, detailed descriptions of the same elements will be omitted.

Referring to FIG. 13, the light-blocking layer BMa may include a plurality of fixing portions FPa. The fixing portions FPa may be provided to fix the light-blocking layer BMa to a predetermined position during a manufacturing method of a display device. A light-blocking hole HO_FPa may be defined through each of the fixing portions FPa along a thickness direction (e.g., the third direction DR3) of the light-blocking layer BMa. The fixing portions FPa may protrude from a second light-blocking area CA2, a third light-blocking area CA3, and a fourth light-blocking area CA4. FIG. 13 shows three fixing portions FPa as an illustrative embodiment, however, the disclosure should not be limited thereto or thereby. In an embodiment, the number of the fixing portions FPa may be two or equal to or greater than four.

FIG. 14 is a plan view of an embodiment of a light-blocking layer BMb according to the disclosure. In FIG. 14, the same reference numerals denote the same elements in FIG. 4, and thus, detailed descriptions of the same elements will be omitted.

Referring to FIG. 14, the light-blocking layer BMb may include a plurality of fixing portions FPb. The fixing portions FPb may be provided to fix the light-blocking layer BMb to a predetermined position during a manufacturing method of a display device. A light-blocking hole HO_FPb may be defined through each of the fixing portions FPb along a thickness direction (e.g., the third direction DR3) of the light-blocking layer BMb. Each of the fixing portions FPb may have a quadrangular shape. FIG. 14 shows three fixing portions FPb as an illustrative embodiment, however, the disclosure should not be limited thereto or thereby. In an embodiment, the number of the fixing portions FPb may be two or equal to or greater than four.

Although the embodiments of the disclosure have been described, it is understood that the disclosure should not be limited to these embodiments but various changes and modifications may be made by one ordinary skilled in the art within the spirit and scope of the disclosure as hereinafter claimed. Therefore, the disclosed subject matter should not be limited to any single embodiment described herein, and the scope of the inventive concept shall be determined according to the attached claims.

What is claimed is:

1. A display device comprising:
a display panel comprising a display area and a non-display area defined adjacent to the display area;
an optical layer disposed on the display panel;
a light-blocking layer disposed on the optical layer and comprising at least one side surface protruding further than a side surface of the optical layer in a cross-section; and
a coating window disposed on the light-blocking layer and comprising a resin material.

2. The display device of claim 1, wherein the coating window comprises a side surface aligned with the at least one side surface of the light-blocking layer.

3. The display device of claim 1, wherein the coating window covers the light-blocking layer and the optical layer.

4. The display device of claim 1, further comprising a driving chip disposed on the display panel and spaced apart from the optical layer in a plan view, wherein the light-blocking layer overlaps an area between the optical layer and the driving chip in the plan view.

5. The display device of claim 1, wherein the light-blocking layer is a rigid substrate overlapping the non-display area and comprising a light-blocking material.

6. The display device of claim 1, wherein the light-blocking layer comprises a first light-blocking area, a second light-blocking area, a third light-blocking area, and a fourth light-blocking area, and the first light-blocking area comprises the at least one side surface, and the first light-blocking area has a width equal to or greater than about 2 millimeters.

7. The display device of claim 6, wherein each of the second light-blocking area, the third light-blocking area, and the fourth light-blocking area has a width smaller than the width of the first light-blocking area.

8. The display device of claim 1, wherein the light-blocking layer has a thickness equal to or greater than about 0.2 millimeter.

9. A method of manufacturing a display device, the method comprising:
placing a display panel on which a driving chip is disposed and an optical layer disposed on the display panel on a first jig;
placing a second jig on the first jig and the display panel in an area adjacent to the driving chip;
placing a light-blocking layer comprising a first light-blocking area, a second light-blocking area, a third light-blocking area, and a fourth light-blocking area on the first jig, the second jig, and the optical layer;
placing a third jig to overlap the second light-blocking area and the fourth light-blocking area:
providing a resin material on the optical layer and the light-blocking layer; and
curing the resin material to form a coating window.

10. The method of claim 9, wherein the first light-blocking area of the light-blocking layer overlaps the second jig and is disposed spaced apart from the driving chip in a cross-section, and the third light-blocking area of the light-blocking layer is disposed to overlap the first jig.

11. The method of claim 9, wherein a plurality of first jig holes is defined through the first jig along a thickness direction of the first jig, the light-blocking layer comprises a plurality of fixing portions through which a plurality of light-blocking holes is respectively defined along a thickness direction of the light-blocking layer, and
wherein the placing the light-blocking layer comprises placing each of the plurality of first jig holes of the first jig and each of the plurality of light-blocking holes of the plurality of fixing portions to overlap each other.

12. The method of claim 11, wherein the third jig comprises a plurality of protruding portions, and
wherein the placing the third jig comprises placing each of the plurality of protruding portions of the third jig to overlap with the plurality of light-blocking holes and the plurality of first jig holes.

13. The method of claim 11, further comprising irradiating a laser beam to cut the plurality of fixing portions.

14. The method of claim 11, wherein the plurality of fixing portions protrudes from at least two light-blocking areas among the second, third, and fourth light-blocking areas.

15. The method of claim 11, wherein each of the plurality of fixing portions has a circular shape, an oval shape, or a quadrangular shape.

16. The method of claim 9, wherein the driving chip is disposed spaced apart from the optical layer on the display panel, and
wherein the placing the light-blocking layer comprises placing the light-blocking layer to overlap with an area between the optical layer and the driving chip in a plan view.

17. The method of claim 9, wherein the light-blocking layer is a rigid substrate comprising a light-blocking material.

18. The method of claim 9, wherein the providing the resin material on the optical layer and the light-blocking layer comprises providing the resin material to an area overlapping an area between the driving chip and the optical layer in a plan view, and the resin material is spaced apart from the display panel.

19. The method of claim 9, wherein the forming the coating window comprises forming a side surface of the coating window so that the side surface of the coating window is aligned with a side surface of the light-blocking layer.

20. The method of claim 9, wherein the forming the coating window comprises forming the coating window to cover the light-blocking layer and the optical layer.
